(19) United States
(12) Patent Application Publication
(10) Pub. No.: US 2010/0319886 A1
(43) Pub. Date: Dec. 23, 2010

(54) HEAT DISSIPATING ASSEMBLY

(75) Inventors: XIANG-KUN ZENG, Shenzhen City (CN); ZHI-GUO ZHANG, Shenzhen City (CN); LI-FU XU, Shenzhen City (CN)

Correspondence Address: Altis Law Group, Inc.;ATTN: Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD, Shenzhen City (CN); HON HAI PRECISION INDUSTRY CO., LTD., Tu-Cheng (CN)

(21) Appl. No.: 12/563,227

(22) Filed: Sep. 21, 2009

(30) Foreign Application Priority Data
Jun. 18, 2009 (CN) 200920304674.5

(51) Int. Cl. F28F 7/00; H05K 7/20

(52) U.S. Cl. 165/122; 165/185

(57) ABSTRACT

A heat dissipating assembly includes a heat exchanger and an air duct. The heat exchanger includes a plurality of fins aligned in a row, and the fins cooperatively define a plurality of heat dissipating channels. A guiding slot is defined in the heat exchanger. The air duct defines a passage. A positioning hook extends from the air duct and engages in the guiding slot to so that the air duct passage and are aligned with the heat dissipating channels so that an air flow is capable of passing through the air duct passage via the heat dissipating channels.

### BACKGROUND

1. Technical Field

The present disclosure relates to heat dissipating assemblies, and particularly, to a heat dissipating assembly with positioning means.

2. Description of Related Art

Electronic devices generate heat during operation. Electronic components in an electronic device may overheat and become damaged if the heat is not dissipated. Some electronic devices use fans and heatsinks to draw heat away. Generally, a heatsink includes a base adhered to an electronic component (such as CPU) which generates heat, and a plurality of fins perpendicularly mounted on the base. The fins define a plurality of air paths configured for allowing air to flow therethrough, and direction of airflow is determined by fans in the electronic device. However, it is common for workers to assemble the heatsink in the electronic device in a wrong direction, for example, with the air paths perpendicular to the direction of the airflow so the fins block airflow and thus heat dissipation is not effective.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, cutaway, isometric view of a heat dissipating assembly, in accordance with an embodiment.

FIG. 2 is similar to FIG. 1, but viewed from another aspect.

FIG. 3 is an assembled view of FIG. 1.

FIG. 4 is an assembled view of FIG. 2.

### DETAILED DESCRIPTION

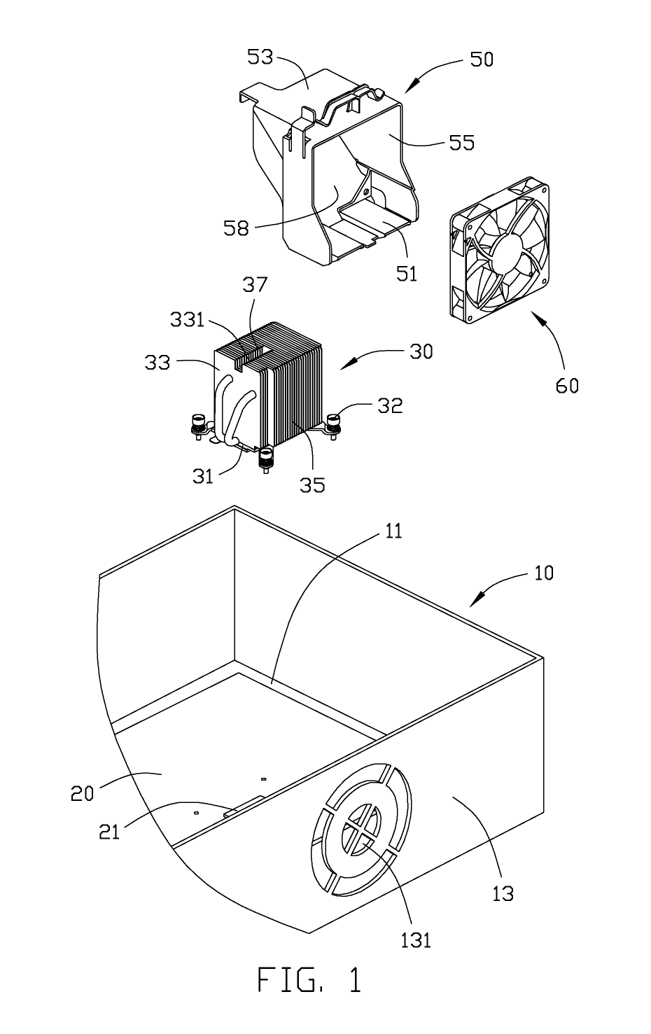

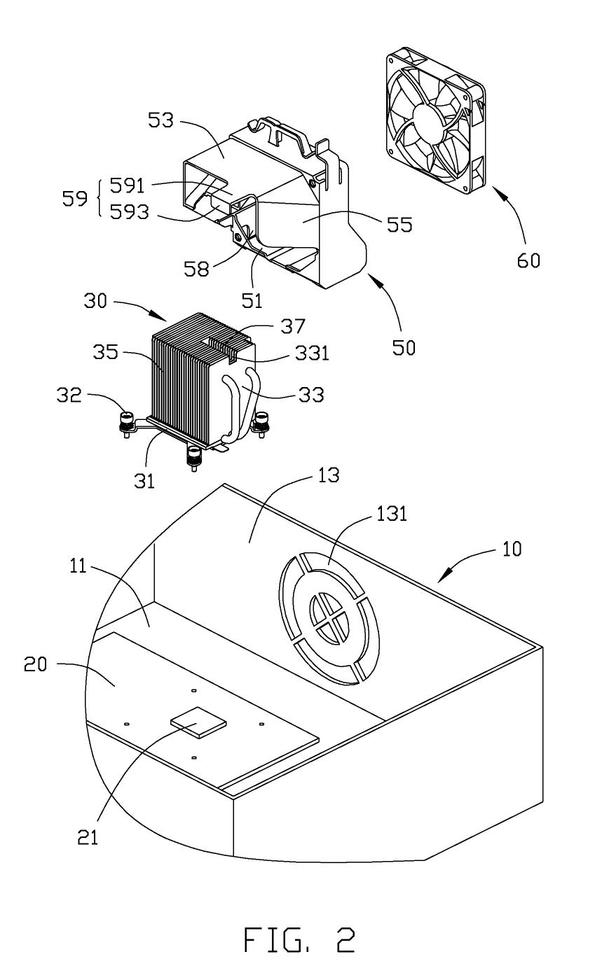

Referring to FIGS. 1 and 2, a heat dissipating assembly in accordance with an embodiment includes a computer chassis 10, a heat dissipating exchanger 30 capable of being mounted in the computer chassis 10, and an air duct 50 capable of being coupled to the heat exchanger 30. The computer chassis 10 includes a bottom wall 11 and a rear wall 13. A motherboard 20 is secured on the bottom wall 11. An electronic component 21, such as a CPU chip or other electronic component that can generate heat, is disposed on the motherboard 20. A heat dissipating aperture 131 is defined in the rear wall 13 of the computer chassis 10.

The heat exchanger 30 includes a seat 31 secured on the motherboard 20. Four securing members 32 are located on four corners of the heat exchanger seat 31. A plurality of parallel fins 33 perpendicularly extend from the heat exchanger seat 31. The fins 33 are arranged in a row and cooperatively define a plurality of heat dissipating channels 35 each positioned between two adjacent fins 33. Some of the fins 33 define a notch 331, and the notches 331 all have the same structure. The notches 331 cooperatively define an elongated guiding slot 37. In one embodiment, the elongated guiding slot 37 is defined in a top of the heat exchanger 30, and a longitudinal extending direction of the guiding slot 37 is perpendicular to the fins 33, and traverses the heat dissipating channels 35. When the heat exchanger 30 is correctly secured in the computer chassis 10, the guiding slot longitudinal extending direction is parallel to the computer chassis rear wall 13.

The air duct 50 includes a bottom wall 51, a top wall 53, and two sidewalls 55 connected to the bottom wall 51 and the top wall 53. The bottom wall 51, the top wall 53, and the two sidewalls 55 cooperatively define an air flow passage 58. A positioning member 59 corresponding to the guiding slot 37 extends from the air duct 50. The positioning member 59 includes a base 591 extending from the top wall 53 and a hook 593 bent from an end of the base 591. The hook 593 is configured to engage in the guiding slot 37.

In alternative embodiments, the positioning member 59 may extend from one of the two sidewalls 55. The guiding slot 37 may be defined in the heat exchanger 30 in a manner which corresponds to the positioning member 59.

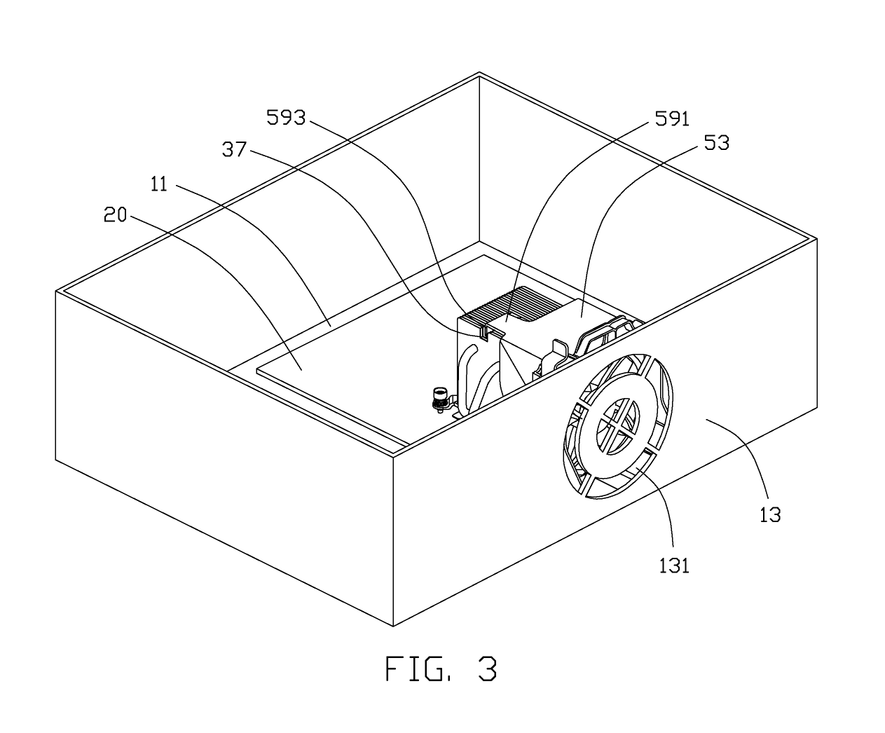

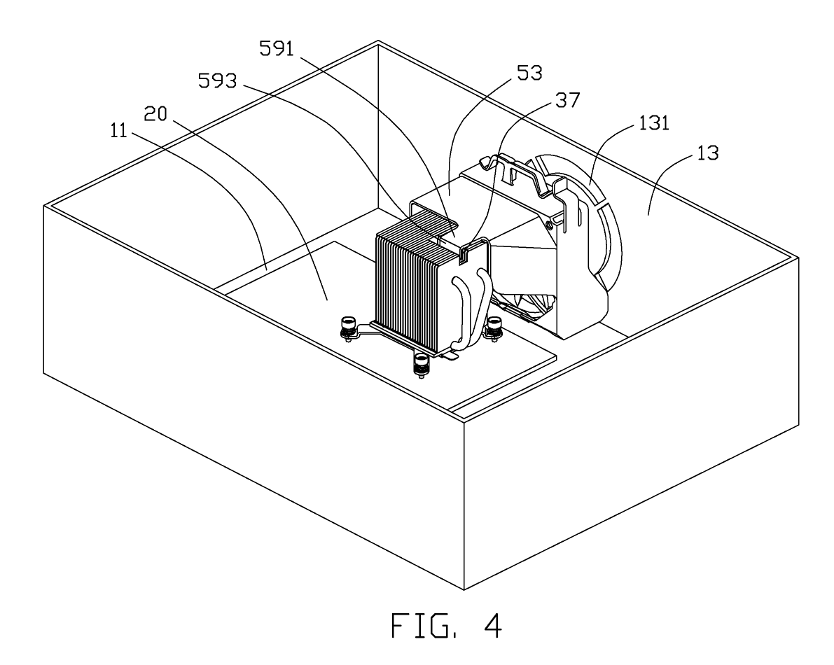

Referring to FIGS. 3 and 4, in assembly, the air duct 50 and a heat dissipating fan 60 are secured to the computer chassis 10. The heat dissipating fan 60 corresponds to the heat dissipating aperture 131 in the computer chassis rear wall 13 and is located in the air duct passage 58, to draw air from outside to the air duct 50. The heat exchanger 30 is adjusted to have the longitudinal direction of the guiding slot 37 being consistent with the positioning member 59 of the air duct 50. Then, the heat exchanger 30 is moved along a direction parallel to the computer chassis rear wall 13, and the hook 593 of the positioning member 59 slides along the guiding slot 37 in the heat exchanger 30 till the heat exchanger 30 is located above the electronic component 21 on the motherboard 20, so that the heat dissipating channels 35 of the heat exchanger 30 face toward the air duct passage 58. Then, the heat exchanger 30 is secured to the motherboard 20 via the securing members 32. When the fan 60 works, air is drawn into the air duct 50 and properly passes through the heat dissipating channels 35 of the heat exchanger 30, to help the electronic component 21 dissipate heat.

Using the above-described heat dissipating apparatus, the heat exchanger 30 can only be assembled in the computer chassis 10 when the heat exchanger 30 is adjusted to a correct mounting direction (the heat dissipating channels 35 facing the air duct passage 58). If the heat dissipating channels 35 do not face the air duct passage 58 before assembly, the heat exchanger 30 will be blocked by the hook 593 of the air duct positioning member 59 and cannot be assembled in the chassis normally, thereby preventing the heat exchanger 30 from being mounted in the computer chassis 10 in a wrong direction.

It is to be understood, however, that even though numerous characteristics and advantages of the embodiments have been set forth in the foregoing description, together with details of the structure and function of the present disclosure, the disclosure is illustrative only, and changes may be made in detail, especially in matters of shape, size, and arrangement of parts within the principles of the embodiments to the full extent indicated by the broad general meaning of the terms in which the appended claims are expressed.

What is claimed is:

1. A heat dissipating assembly, comprising:
a heat exchanger having a plurality of fins aligned in a row, the fins cooperatively defining a plurality of heat dissipating channels, a guiding slot defined in the heat exchanger; and
an air duct defining a passage, a positioning member extending from the air duct and engaged in the guiding slot so that the heat dissipating channels are aligned with the passage, so that air flow is capable of passing through the air duct passage and the heat dissipating channels.

2. The heat dissipating assembly of claim 1, wherein some of the heat exchanger fins define a notch, the notches cooperatively define the guiding slot.

3. The heat dissipating assembly of claim 2, wherein a longitudinal extending direction of the guiding slot traverses the heat dissipating channels.

4. The heat dissipating assembly of claim 1, wherein the air duct comprises a top wall, a bottom wall, and two sidewalls, which cooperatively define the air flow passage; the positioning member comprises a base extending from the air duct top wall and a hook bent from the base; and the base abuts the heat exchanger fins.

5. The heat dissipating assembly of claim 4, further comprising a chassis having the heat exchanger and the air duct mounted thereon, and the chassis having a rear wall which defines a heat dissipating aperture corresponding to the air duct passage.

6. The heat dissipating assembly of claim 5, wherein a longitudinal extending direction of the guiding slot is parallel to the chassis rear wall.

7. A heat dissipating assembly, comprising:
a chassis having a bottom wall, an electronic component disposed on the bottom wall;
a heat exchanger located above the electronic component, the heat exchanger defining a guiding slot; and
an air duct having a positioning member, the positioning member engage in the guiding slot to ensure the air duct to couple to the heat exchanger from a determined direction so that air flow is capable of passing through the air duct and the heat exchanger.

8. The heat dissipating assembly of claim 7, wherein the heat exchanger comprises a plurality of fins, the plurality of fins cooperatively define a plurality of heat dissipating channels, and the air duct defines a passage facing toward the heat dissipating channels.

9. The heat dissipating assembly of claim 8, wherein the chassis has a rear wall perpendicular to the bottom wall, the rear wall defines a heat dissipating aperture corresponding to the air duct passage.

10. The heat dissipating assembly of claim 9, wherein the guiding slot is elongated, and a longitudinal extending direction of the guiding slot is parallel to the chassis rear wall.

11. The heat dissipating assembly of claim 8, wherein some of the heat exchanger fins define a notch, the notches cooperatively define the guiding slot.

12. The heat dissipating assembly of claim 8, wherein the air duct comprises a top wall, a bottom wall, and two sidewalls, which cooperatively define the air flow passage; the positioning member comprises a base extending from the air duct top wall and a hook bent from the base; the base abuts the heat exchanger fins; and the positioning hook is received in the guiding slot.

13. The heat dissipating assembly of claim 8, wherein the guiding slot is elongated, and a longitudinal extending direction of the guiding slot traverses the heat dissipating channels.
